(19) United States
(12) Patent Application Publication
(10) Pub. No.: US 2009/0236534 A1
(43) Pub. Date: Sep. 24, 2009

(54) Pixelated Scintillation Detector and Method of Making Same

(75) Inventors: Thomas A. Selfe, Huntsburg, OH (US); Daniel J. Herr, Twinsburg, OH (US); Peter R. Menge, Chagrin Falls, OH (US)

Correspondence Address: Saint-Gobain/GTPP, 55 South Commercial Street, Manchester, NH, 03101, US

(73) Assignee: SAINT-GOBAIN CERAMICS & PLASTICS, INC., Worcester, MA (US)

(21) Appl. No.: 12/406,174

(22) Filed: Mar. 18, 2009

Related U.S. Application Data
(60) Provisional application No. 61/037,473, filed on Mar. 18, 2008.

(51) Int. Cl. G01T 1/20; H01L 21/00

(52) U.S. Cl. 250/370.11; 438/73; 257/E21.001; 250/361 R

(57) ABSTRACT

A scintillation detector may include a pixelated scintillation crystal mechanically and optically coupled to a position sensitive photodetector, such as a position sensitive photomultiplier tube (PSPMT). The pixelated scintillation crystal may be coupled to the position sensitive photodetector without using a window between the crystal and photodetector. According to one method of constructing the scintillation detector, a solid scintillation crystal may be coupled to the position sensitive photodetector and cut while coupled to the photodetector to form the pixelated scintillation crystal.

### CROSS-REFERENCE TO RELATED APPLICATIONS

The present application claims the benefit of U.S. Provisional Application Ser. No. 61/037,473 filed on Mar. 18, 2008, which is fully incorporated herein by reference.

### TECHNICAL FIELD

The present invention relates to radiation detectors and more particularly, to a pixelated scintillation detector and method of making same.

### BACKGROUND INFORMATION

Scintillation detectors are generally used to detect radiation that is not easily detected by conventional photodetectors. A scintillator or scintillation crystal absorbs the radiation and converts the energy of the radiation to a light pulse. The light may be converted to electrons (i.e., an electron current) in a photomultiplier tube, which amplifies the electron current. Scintillation detectors may be used in various industries and applications including medical (e.g., to produce images of internal organs), geophysical (e.g., to measure radioactivity of the earth), inspection (e.g., non-destructive, non-invasive testing), research (e.g., to measure the energy of photons and particles), and health physics (e.g., to monitor radiation in the environment as it affects humans).

Position sensitive photomultiplier tubes (PSPMT) have been developed, which are capable of position detection. The development of PSPMTs has resulted in the use of pixellated detectors (versus solid crystal) to provide position sensitivity. Cutting the crystal into pixels before the crystal is coupled to the PSPMT presents challenges, however, because assembling and coupling the crystal pixel elements is difficult. The manufacturing of a pixelated scintillation detector also presents challenges because the crystals may have certain properties (e.g., hygroscopicity) that require handling the crystals in a certain way and because the PSPMT is susceptible to damage and should be protected.

According to one technique, a crystal may be coupled to an optical window and then cut to form a pixelated crystal. Because some scintillation crystals are hygroscopic and fragile, the crystal must be cut under certain conditions to prevent damage to the crystal. The optical window acts as a substrate for the crystal and allows the crystal to be cut separately from the PSPMT, which is also susceptible to damage from the cutting process. Although the optical window allows the crystal to be cut with the desired pixel uniformity, the use of the window may adversely affect performance in the assembled scintillation detector. In particular, the window may cause the light emitted from the pixelated crystal to spread, which degrades the positional resolution of the detector. Performance may also be degraded because optical coupling materials are used on each side of the window to couple the crystal and the PSPMT, which may provide an index of refraction mismatch and transmission losses. Because the optical window acts as a substrate for the crystal during cutting and is also part of a hermetic package for the scintillation detector (e.g., to protect a hygroscopic scintillation crystal), elimination of the window is not trivial.

### SUMMARY

Consistent with one aspect, a scintillation detector includes a position sensitive photodetector, an array of crystal pixel elements, and an optical coupling material between the position sensitive photodetector and the array of crystal pixel elements. The optical coupling material mechanically and optically couples the array of crystal pixel elements directly to the position sensitive photodetector.

Consistent with another aspect, a method of making a scintillation detector includes: applying an optical coupling material between a scintillation crystal and a position sensitive photodetector to mechanically and optically couple the scintillation crystal and the position sensitive photodetector; cutting the scintillation crystal while coupled to the position sensitive photodetector to form a pixelated scintillation crystal including an array of crystal pixel elements; and applying a reflective material to the array of crystal pixel elements.

Consistent with a further aspect, is method is provided for detecting radiation. This method includes: providing a pixelated scintillation detector including a position sensitive photodetector and an array of crystal pixel elements mechanically and optically coupled directly to the position sensitive photodetector using an optical coupling material without a window; applying radiation to the array of crystal pixel elements; producing an output from the position sensitive photodetector in response to excitatory radiation; and processing the output from the position sensitive photodetector to produce detected radiation information corresponding to each of the pixel elements in the array of crystal pixel elements. The detected radiation information includes at least a flood image having an improved spatial resolution as compared to a flood image generated under the same conditions by a pixelated scintillation detector including an array of crystal pixel elements coupled to a position sensitive photodetector with a window.

Consistent with yet another aspect, pixelated scintillation detection system includes a pixelated scintillation detector including a position sensitive photodetector and an array of crystal pixel elements mechanically and optically coupled directly to the position sensitive photodetector using an optical coupling material without a window. The pixelated scintillation detection system further includes a signal processing system configured to process the output from the position sensitive photodetector to produce detected radiation information corresponding to each of the pixel elements in the array of crystal pixel elements. The detected radiation information includes at least a flood image having an improved spatial resolution as compared to a flood image generated under the same conditions by a pixelated scintillation detector including an array of crystal pixel elements coupled to a position sensitive photodetector with a window.

### BRIEF DESCRIPTION OF THE DRAWINGS

These and other features and advantages will be better understood by reading the following detailed description, taken together with the drawings wherein:

FIG. 1 is a partially cross-sectional side view of a pixelated scintillation detector, consistent with an embodiment.

FIGS. 2A-2G are side views illustrating a method of assembling the pixelated scintillation detector shown in FIG. 1.

FIG. 3 is a side view of one embodiment of a fixture configured to secure a photodetector while machining the scintillation crystal to form a pixelated scintillation crystal.

FIG. 4 is a partially cross-sectional side view of a pixelated scintillation detector, consistent with another embodiment.

FIG. 5 is a partially cross-sectional side view of a pixelated scintillation detector, consistent with a further embodiment.

FIG. 6 is a side schematic view of a detection system including a pixelated scintillation detector, consistent with an embodiment.

FIG. 7 is a top schematic view of a pixel array on an array of anodes in a position sensitive photomultiplier tube (PSPMT), according to a first exemplary simulation of a pixelated scintillation detection system.

FIGS. 8A and 8B are simulated flood images generated for the pixelated scintillation detection system illustrated in FIG. 7 with a window and without a window, respectively.

FIG. 9 is a top schematic view of a pixel array on an array of anodes in a position sensitive photomultiplier tube (PSPMT), according to a second exemplary simulation of a pixelated scintillation detection system.

FIGS. 10A and 10B are simulated flood images generated for the pixelated scintillation detection system illustrated in FIG. 9 with a window and without a window, respectively.

FIGS. 11A and 11B are simulated histograms corresponding to the rows of pixels illustrated in the simulated flood images shown in FIGS. 10A and 10B, respectively.

FIG. 12A illustrates simulated flood images corresponding to different pixel sizes in simulated pixelated scintillation detection systems with a window.

FIG. 12B illustrates simulated flood images corresponding to different pixel sizes in simulated pixelated scintillation detection systems without a window.

FIG. 13 is a graph illustrating modulation transfer functions for a simulated pixelated scintillation detection system without a window as compared to a simulated pixelated scintillation system with a window.

### DETAILED DESCRIPTION

In general, a pixelated scintillation detector, consistent with embodiments described herein, includes a pixelated scintillation crystal mechanically and optically coupled to a position sensitive photodetector. The pixelated scintillation crystal may be coupled to the position sensitive photodetector without using a window between the crystal and photodetector. According to one method of constructing the scintillation detector, a solid scintillation crystal may be coupled to the position sensitive photodetector and cut while coupled to the photodetector to form the pixelated scintillation crystal.

As used herein, the term “radiation” includes electromagnetic radiation and high-energy particles (e.g., gamma radiation, alpha particles and beta particles). The term “light” includes electromagnetic radiation of any wavelength and is not limited to visible light. The term “scintillation crystal” refers to a crystal material that emits light (“scintillation light”) in response to electromagnetic radiation incident thereon (“excitatory radiation”). As used herein, the term “coupled” may refer to either a mechanical coupling or an optical coupling and does not imply a direct coupling or connection unless otherwise specified. As used herein, the term “optically coupled” refers to at least one coupled element being adapted to impart light to another coupled element directly or indirectly.

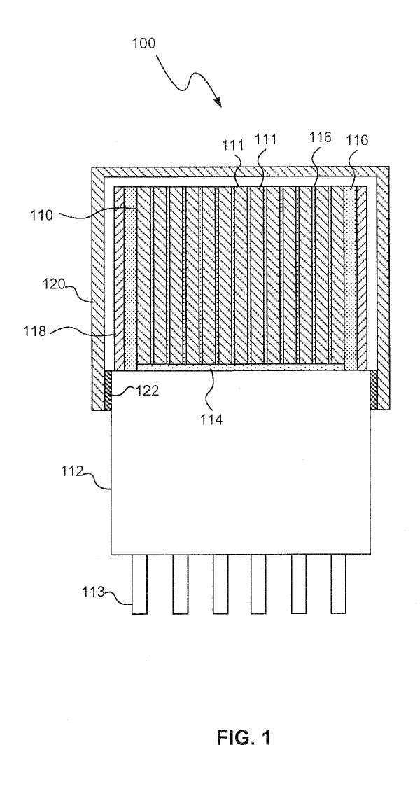

Referring to FIG. 1, an embodiment of a pixelated scintillation detector 100 includes a pixelated scintillation crystal 110 mechanically and optically coupled to a position sensitive photodetector 112 using an optical coupling material 114. The pixelated scintillation crystal 110 includes an array of crystal pixel elements 111, which may be formed before or after the crystal 110 is coupled to the photodetector 112, as will be described in greater detail below. The pixelated scintillation crystal 110 may also include slots between the crystal pixel elements 111, which extend at least partially through the crystal 110. Each of the crystal pixel elements 111 may provide scintillation light in response to excitatory radiation, and the position sensitive photodetector 112 provides an output in response to detecting the scintillation light provided by each of the crystal pixel elements 111. The output from the position sensitive photodetector 112 may be used to determine the energy of the detected radiation, the amount of detected radiation (i.e., the number of particles hitting the scintillation detector 100) and/or the position at which the detected radiation hits the scintillation detector 100.

The scintillation crystal 110 may be coupled directly to the photodetector 112 with the optical coupling material 114 without using a window between the scintillation crystal 110 and the photodetector 112. In other words, the optical coupling material 114 may be the only material located between the crystal 110 and the photodetector 112. The optical coupling material 114 may include any material capable of adhering to the crystal 110 and the material of the photodetector 112 (e.g., glass) and having an index of refraction and/or other optical transmission characteristics, for example, that allow scintillation light to pass through with minimal attenuation and scattering. One example of such an optical coupling material is a clear optical epoxy.

The optical coupling material 114 may be sufficiently thick to adhere and may be sufficiently thin to allow scintillation light to be coupled into the photodetector 112 with minimal or no spreading. According to an embodiment, the optical coupling material 114 may also be sufficiently thick to prevent damage to the photodetector 112 when the pixelated scintillation crystal 110 is cut while coupled to the photodetector 112. The optical coupling material 114 may also be as thick as the combined thickness of the optical coupling material and window in the existing scintillation detectors with windows. Even at the same thickness, performance may be improved because the use of the optical coupling material 114 without the window eliminates the mismatch in refractive indices. In one embodiment, the thickness of the optical coupling material 114 may range between about ¼ mm and 2½ mm and more particularly may range between about ¼ mm and 1½ mm.

The pixelated scintillation crystal 110 may be constructed from various types of crystal capable of being used in scintillation detectors. According to one embodiment, the scintillation crystal 110 is a hygroscopic crystal such as thallium doped sodium iodide—Na(TI)—or cerium-doped lanthanum bromide—LaBr₃(Ce). Other hygroscopic or non-hygroscopic scintillation crystals may also be used such as, for example, cesium iodide—CsI—and lutetium yttrium orthosilicate—LYSO.

The position sensitive photodetector 112 may include one or more photodetector devices capable of detecting and measuring scintillation light and capable of providing an output indicative of a position of the detected scintillation light relative to the photodetector 112. The position sensitive photodetector 112 may include a single photodetector device with separate detection regions corresponding to the positions at which the scintillation light may be detected. The position sensitive photodetector 112 may also include a plurality of separate non-position-sensitive photodetector devices corresponding to the different positions at which the scintillation light is detected. The position sensitive photodetector 112 may include a position sensitive photomultiplier tube (PSPMT) including an array of electrically isolated anodes capable of detecting scintillation light, such as the type currently available and known to those skilled in the art. Other types of photodetectors that may be used include photodiodes. The position sensitive photodetector 112 may also include one or more output paths 113 (e.g., wires or pins) extending from the photodetector 112 to carry the output signal from the photodetector 112.

The pixelated scintillation crystal 110 may be configured such that each of the crystal pixel elements 111 detects radiation and transmits scintillation light independently of other crystal pixel elements 111. Thus, radiation may be measured for each of the individual pixel elements 111 in the scintillation detector 100. The individual pixel elements 111 may not have homogeneous properties. To optically isolate the scintillation light in the pixel elements 111, a reflective material 116 may be provided around and between the crystal pixel elements 111. In one embodiment the reflective material 116 may be a powdered reflective material, such as aluminum oxide or magnesium oxide, which fills the spaces or slots around and between the crystal pixel elements 111. The scintillation detector 110 may include a retaining structure, such as ring 118, extending around the pixelated scintillation crystal 110 to retain the powdered reflective material. Other types and forms of reflective materials may also be used, such as, for example, a sheet reflector.

A housing 120 may be secured to the photodetector 112 and encloses the pixelated scintillation crystal 110. The housing 120 may be constructed from aluminum or other suitable material known to those skilled in the art for use in a housing of a scintillation detector. The housing 120 may be hermetically sealed to the photodetector 112 to protect the scintillation crystal 110, for example, when the crystal 110 is hygroscopic. To provide the hermetic sealing, a seal 122 may be formed around the sides of the photodetector 112 and against the housing 120. The seal 122 may be formed using any sealing compound or material capable of adhering to the materials of the housing 120 (e.g., aluminum) and the photodetector 112 (e.g., glass) and capable of providing hermetic sealing properties. One example of such a sealing compound is an epoxy. When the scintillation crystal 110 is non-hygroscopic, hermetic sealing may be unnecessary and a seal capable of shielding from external light may be used. Other types of adhesives or methods for securing the housing 120 to the photodetector 112 may also be used.

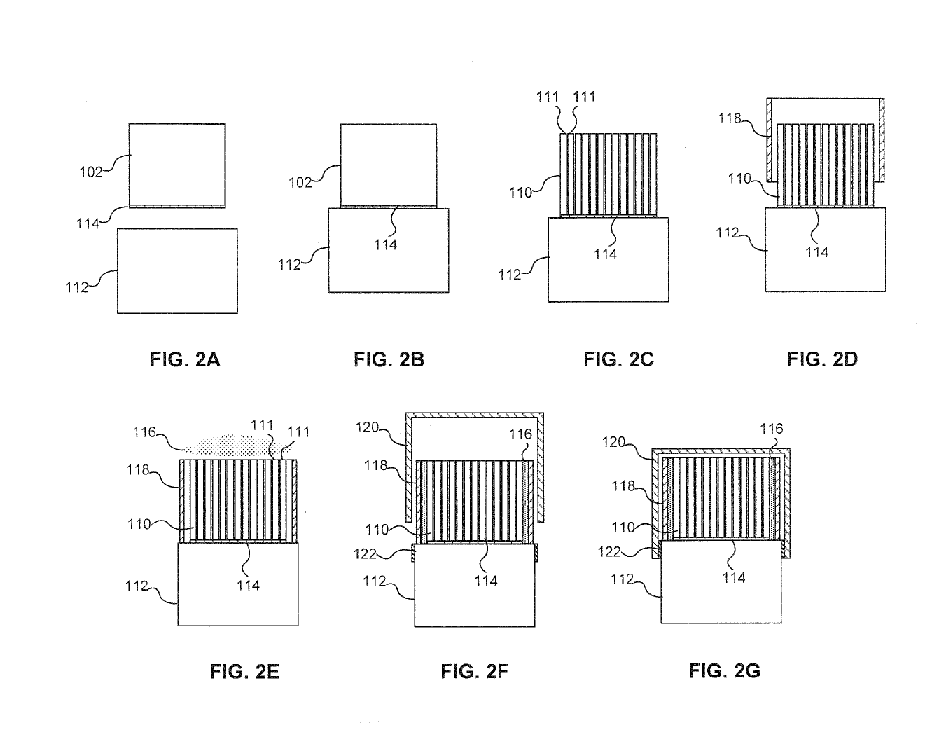

Referring to FIGS. 2A-2G, one method of making the scintillation detector 100 is shown and described in greater detail. The optical coupling material 114 may be applied with the appropriate thickness to the position sensitive photodetector 112 and/or to a solid scintillation crystal 102 (FIG. 2A). The photodetector 112 and the solid scintillation crystal 102 may then be held together against the optical coupling material 114 (e.g., until the optical coupling material cures or hardens) such that the solid scintillation crystal 102 and the photodetector 112 are mechanically and optically coupled (FIG. 2B).

The solid scintillation crystal 102 may then be cut to form the pixelated scintillation crystal 110 including the array of crystal pixel elements 111 (FIG. 2C). The machining generally includes dicing or cutting the crystal 102 from an outer end of the crystal 102 to the optical coupling material 114 to form slots separating the crystal pixel elements 111. The slots may be formed by cutting completely through the solid scintillation crystal 102 to the optical coupling material 114. The slots may also be formed by cutting almost completely through the solid scintillation crystal 102 leaving a portion of the crystal 102 intact, provided that the desired optical isolation is maintained when scintillation light is coupled from the crystal pixel elements 111 into the photodetector 112.

The solid scintillation crystal 102 may be cut, for example, using a wet cutting process. According to one example of a wet cutting process, the scintillation crystal 102 may be immersed in a liquid coolant and cut using a blade. For hygroscopic crystal, the liquid coolant may be a non-aqueous liquid coolant such as oil. The position sensitive photodetector 112 may be secured in a fixture in a way that protects the photodetector 112 from the coolant and/or other byproducts of the machining process, as will be described in greater detail below. The scintillation crystal 102 may also be cut using other wet or dry cutting techniques, such as electrical discharge machining, wire saw or laser ablation.

The retaining ring 118 may then be positioned around the pixelated scintillation crystal 110 (FIG. 2D). The retaining ring 118 may be secured to the photodetector 112, for example, using a suitable adhesive. The reflective material 116 may then be applied to the pixelated scintillation crystal 110 such that the reflective material 116 passes into the slots between the crystal pixel elements 111 and in the regions around the outside of the crystal pixel elements 111 (FIG. 2E). The reflective material 116 may be retained by the retaining ring 118.

The housing 120 may then be positioned over the pixelated scintillation crystal 110 and secured to the photodetector 112. In particular, the sealing material or compound that forms the hermetic seal 122 may be applied to the photodetector 112 and/or to the inner surface of the housing 120 (FIG. 2F). The housing 120 may then be positioned in place and secured with the hermetic seal 122 between the housing 120 and the photodetector 112 (FIG. 2G).

Other methods may also be used to mechanically and optically couple the pixelated scintillation crystal 110 to the position sensitive photodetector 112. In particular, the array of crystal pixel elements 111 may be formed before coupling to the photodetector 112.

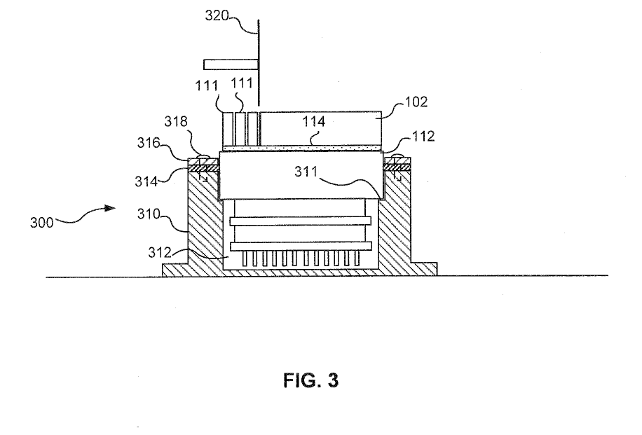

FIG. 3 shows one embodiment of a fixture 300 that may be used to secure and protect the photodetector 112 during cutting of the solid scintillation crystal 102 with a cutting tool 320 to form the crystal pixel elements 111. The fixture 300 may include a fixture base portion 310 that defines a cavity 312 configured to receive at least a portion of the photodetector 112. The photodetector 112 may be held in the fixture 300 such that a relatively small portion (or no portion) of the photodetector 112 is exposed to the coolant used in the cutting process or other byproducts of the cutting process. The fixture base portion 310 may include a shelf or outwardly extending portion 311 that engages a portion of the photodetector 112 and supports the photodetector 112 at the desired position.

The fixture 300 may include a seal 314 that engages and seals around an outside of the photodetector 112 to prevent any of the coolant or cutting debris from reaching the remaining unexposed portion of the photodetector 112. In the illustrated embodiment, the seal 314 may be held in place by a clamping member 316 and one or more fasteners 318. The seal 314 may be made of any material capable of sealing against an outside surface of the photodetector 112 and preventing the coolant from passing. Other embodiments of the fixture may also be used to secure and protect the position sensitive photodetector 112 during the cutting process.

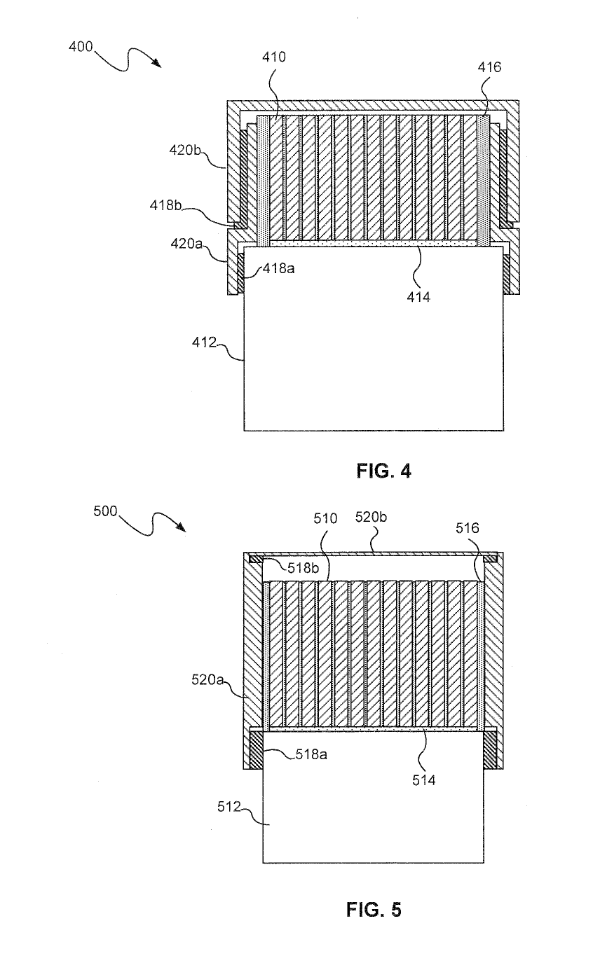

Referring to FIG. 4, another embodiment of a scintillation detector 400 may include a pixelated scintillation crystal 410 mechanically and optically coupled to a photodetector 412 with an optical coupling material 414 and a multiple piece housing 420a, 420b enclosing the pixelated scintillation crystal 410. The multiple piece housing 420a, 420b may include a first housing portion 420a secured to the photodetector 412 and a second housing portion 420b secured to the first housing portion 420a. During manufacture, the first housing portion 420a may secured to the photodetector 412 first and used to retain a reflective material 416 similar to the retaining structure described above. The first housing portion 420a may be hermetically sealed to the photodetector using a seal 418a capable of adhering to the materials of the housing portion 420a and the photodetector 412 (e.g., metal and glass). The first housing portion 420a may be hermetically sealed to the second housing portion 420b using a seal 418b capable of adhering to the materials of the housing portions 420a, 420b (e.g., metal).

Referring to FIG. 5, a further embodiment of a scintillation detector 500 with a multiple piece housing 520a, 520b is shown. This embodiment of the scintillation detector 500 includes a first housing portion 520a that extends around a pixelated scintillation crystal 510, which is optically coupled to a photodetector 512 with an optical coupling material 514. The first housing portion 520a may be used to retain a reflective material 516 against the pixelated scintillation crystal 510. The scintillation detector 500 also includes a second housing portion 520b that covers the end portion of the scintillation crystal 510. The first housing portion 520a may be hermetically sealed to the photodetector 512 with a seal 518a and the second housing portion 520b may be hermetically sealed to the first housing portion 520a with a seal 518b. As discussed above, the hermetic seals may be provided by using an epoxy or other suitable material. Other methods for securing the housing portions may also be used such as, for example, welding the housing portions together.

Although specific embodiments are illustrated and described herein, other embodiments are possible. For example, the housing or housing portions may have different configurations. The pixelated scintillation crystal may also have different configurations with different numbers and sizes of crystal pixel elements.

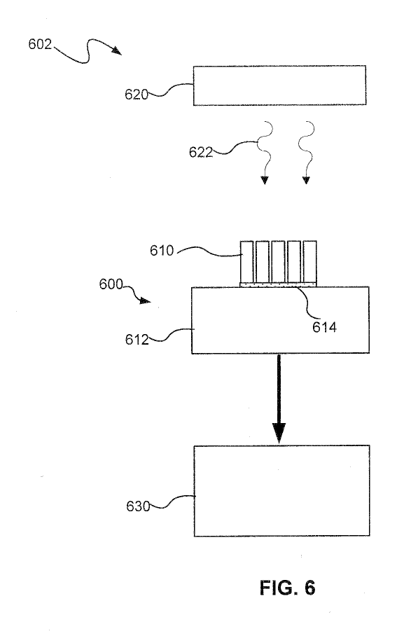

Referring to FIG. 6, pixelated scintillation detector 600, consistent with the embodiments describe above, may be used in a detection system 602. The pixelated scintillation detector 600 may be positioned relative to a radiation source 620 such that radiation 622 from the radiation source 620 impinges upon a pixelated scintillation crystal 610 including an array of crystal pixel elements resulting in radiation events. The pixel elements of the pixelated scintillation crystal 610 convert the excitatory radiation from the radiation events into scintillation light, which passes through an optical coupling material 614 to a position sensitive photodetector 612. The detection devices or regions of the position sensitive photodetector 612 (e.g., anodes of a PSPMT) detect the scintillation light and generate electrical outputs representing the scintillation light generated from the detected radiation events.

A signal processing system 630 may be coupled to the position sensitive photodetector 612 of the pixelated scintillation detector 600 to process the electrical output from the photodetector 612 and produce detected radiation event information. The signal processing system 630 may include electronic circuits, devices or equipment that receive, analyze, and/or process the electrical output from the photodetector 612. In an embodiment, for example, signal processing system 630 may include one or more amplifiers that collect the charge outputs from the detection devices or regions of the photodetector 612 and generate corresponding voltage pulses. The signal processing system 630 may also include a multi-channel analyzer to measure the voltage pulses and store counts corresponding to the measured voltage pulses (i.e., counts per channel). The signal processing system 630 may further include data processing circuitry and/or software to process the voltage pulses and/or stored counts, for example, by computing centroids of the detected events represented by the voltage pulses and/or counts and by producing images representing detected events using positioning techniques, such as Anger logic, which are generally known to those skilled in the art.

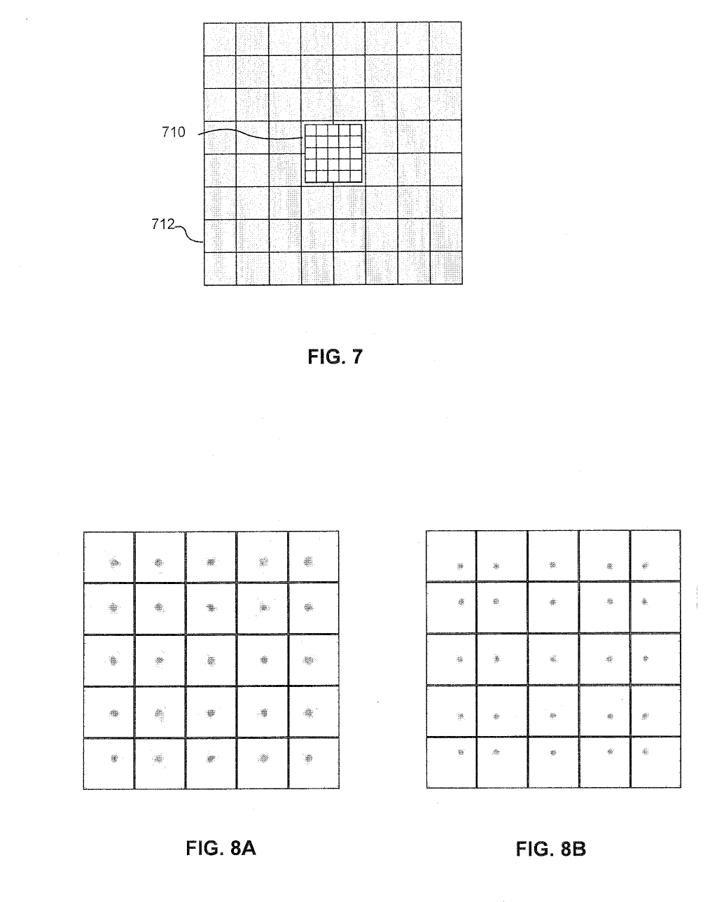

Referring to FIGS. 7-11B, simulated detection systems using different embodiments of a pixelated scintillation detector are described. The simulations described herein are intended to illustrate possible advantages of embodiments of the pixelated scintillation detector described herein and are not necessarily a limitation on the scope of the invention. According to the simulations, a pixelated scintillation detector with a glass window was compared to a pixelated scintillation detector without a glass window consistent with embodiments described herein. The simulated pixelated scintillation detector without the glass window includes a 25 Nal(TI) pixel array coupled directly to a PSPMT with a 0.25 mm thick epoxy layer. The simulated pixelated scintillation detector with the glass window includes a 25 Nal(TI) pixel array coupled to a 2 mm thick glass plate with 0.25 mm thick epoxy and a PSPMT coupled to the glass plate with a 0.25 mm thick optical coupling material.

According to a first simulation, as shown in FIG. 7, a 25 Nal(TI) pixel array 710 with pixel dimensions 2×2×6 mm (aspect ratio of 3) was simulated on a 64-anode PSPMT 712 representing a PSPMT known as the H8500 PSPMT. The simulated pixels in the array 710 are separated and optically isolated by 0.2 mm septa made of opaque diffuse reflector. The simulated PSPMT 712 is a square photomultiplier tube (52×52 mm) tiled with 64 electrically isolated anodes each about 6×6 mm. A simulated radiation source generated 2000 gamma-ray events (E_{γ}=511 keV) and the resulting scintillation light was generated in each pixel. Every scintillation photon was tracked until it reached a PSPMT anode, was absorbed by the reflector, was absorbed by the optical materials, or escaped the simulation. Each gamma-ray event was positioned by the photon number weighted position of the detecting anode using Anger logic positioning techniques known to those skilled in the art, and a simulated flood field image of the pixels was generated (FIGS. 8A and 8B).

FIG. 8A shows the flood field image generated for the simulated pixelated scintillation detector with the glass window and FIG. 8A shows the flood field image generated for the simulated pixelated scintillation detector without the glass window. The simulated flood images are shown superimposed on the actual pixel positions of the simulated pixel array 710. Ideally, the Anger positioning should result in the pixel centroid being imaged in the center of the actual pixel position. The flood image shown in FIG. 8B shows that the pixel positioning appears to be more off-center for the simulation with the pixel array coupled directly to the PSPMT. This may be due to the light not spreading far enough to illuminate enough anodes to accurately compute the pixel centroid. Thus, the pixelated scintillation detector without the glass window appears to result in a centroid calculation that is more precise but less accurate. In other words, the simulation indicates that the spatial resolution may be improved but the distortion may be worse. The positioning algorithm may be modified to correct this distortion and improve the accuracy of the centroid computation, for example, by computing the roll-off function for each anode and folding that in to the computation. With respect to energy resolution, this simulation indicated that the light output when the array is directly coupled without a window is about 1% greater than the light output when the array is coupled to the glass window.

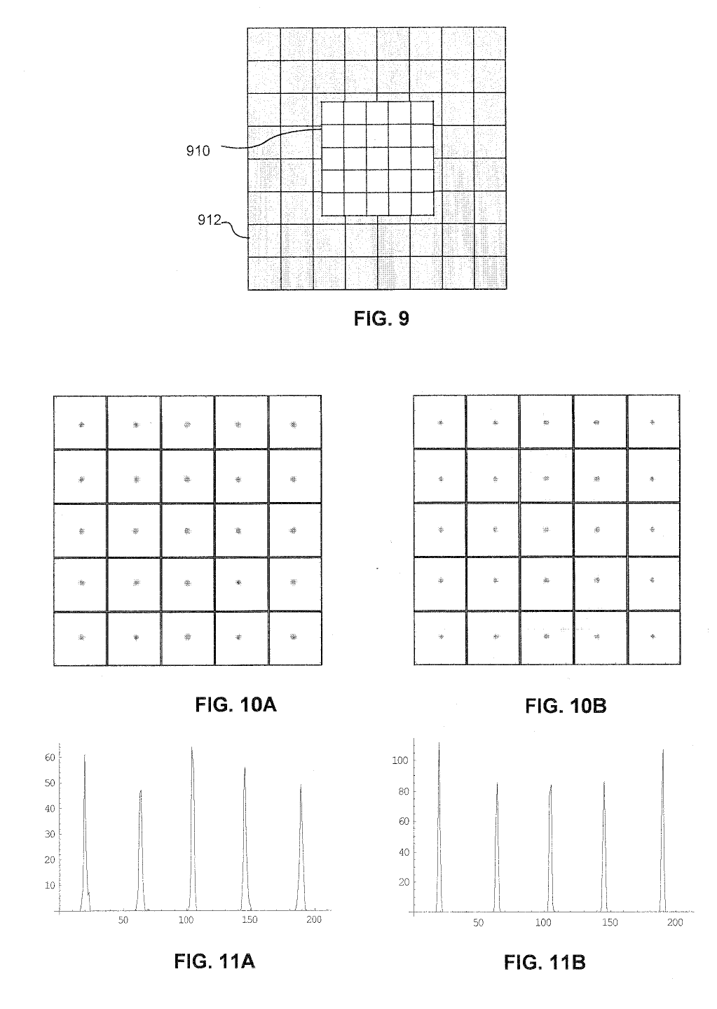

According to a second simulation, as shown in FIG. 9, a 25 Nal(TI) pixel array 910 was simulated on a 256-anode PSPMT 912 representing a PSPMT known as the H9500 PSPMT. In this simulation, the size of pixels in the pixel array 910 has also been increased by a factor of 2×. The other parameters of the simulation are the same as stated above. FIG. 10A shows the flood field image generated for the simulated pixelated scintillation detector with the glass window and FIG. 10B shows the flood field image generated for the simulated pixelated scintillation detector without the glass window. FIG. 10B shows that the images produced by this simulation are more accurately centered on the pixels for the simulated pixelated scintillation detector without the window. Thus, this simulation appears to eliminate the distortion because more anodes are involved in computing the pixel centroids. This simulation also shows that the pixels are better resolved as compared to the pixelated scintillation detector with the glass window. FIGS. 11A and 11B show histograms corresponding to the rows of pixels in FIGS. 10A and 10B, respectively. The narrower width of the histogram peaks shown in FIG. 11B indicates an improved spatial resolution as compared to the pixelated scintillation detector with the glass window represented by the histogram in FIG. 11A.

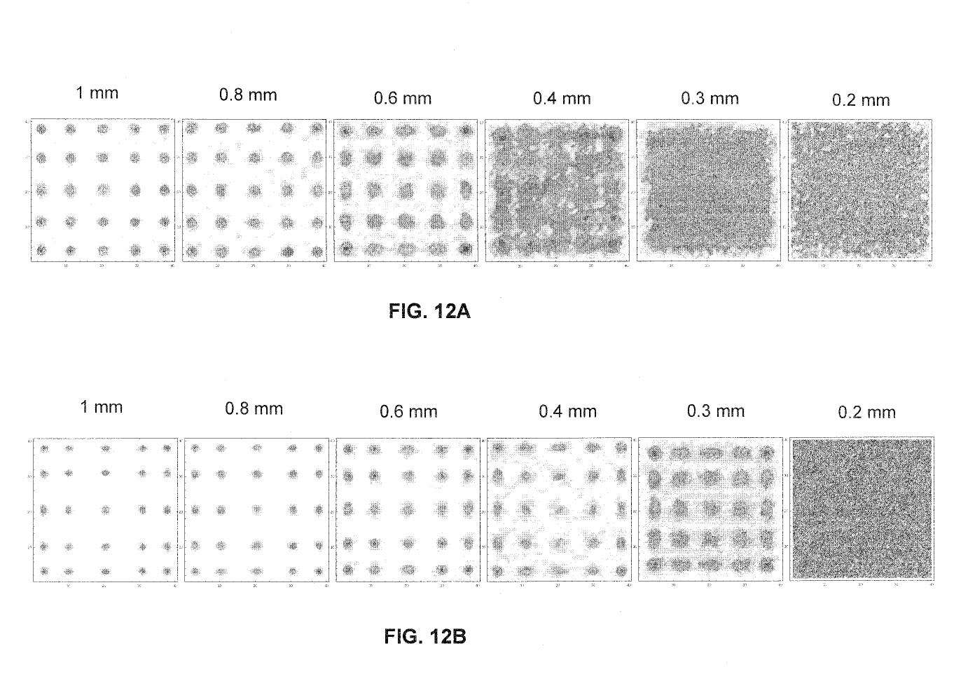

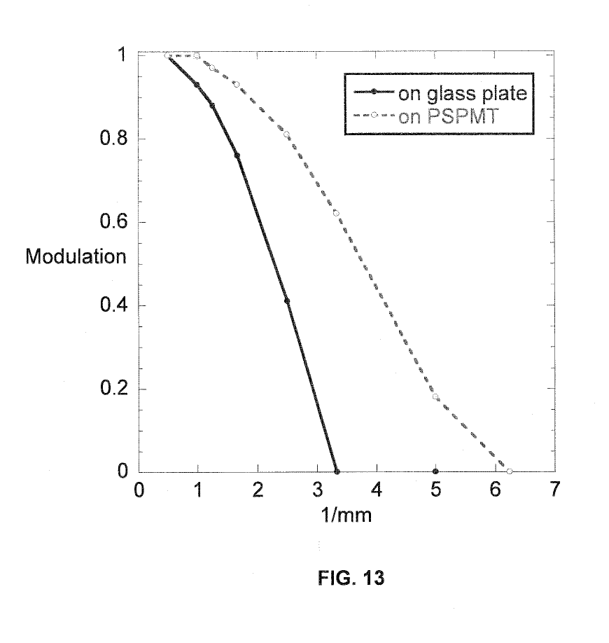

FIGS. 12A, 12B and 13 illustrate additional simulations similar to the simulation described above in connection with FIG. 7 but with varying pixel dimensions. The pixel dimensions were varied while maintaining an aspect ratio of 3, resulting in the following simulated pixel sizes: 2×2×6 mm; 1×1×3 mm; 0.8×0.8×2.4 mm; 0.6×0.6×1.8 mm; 0.4×0.4×1.2 mm; 0.3×0.3×0.9 mm; 0.2×0.2×0.6 mm; and 0.16×0.16×0.48 mm. FIGS. 12A and 12B illustrate the flood images for pixel sizes ranging from 1 mm to 0.2 mm with the flood images in FIG. 12A being generated by the simulated pixelated scintillation detector with the window and the flood images in FIG. 12B being generated by the simulated pixelated scintillation detector without the window. A comparison of FIGS. 12A and 12B shows that a simulated pixelated scintillation detector without a window produces flood images that are better resolved at most pixel sizes. In particular, at smaller pixel sizes of 0.4 and 0.3 mm, the pixels are clearly resolved in the simulated flood images shown in FIG. 12B, whereas the simulated flood images shown in FIG. 12A for the same pixel sizes of 0.4 and 0.3 mm are not clearly resolved.

To further compare the improvement in resolution, the average pixel modulation may be calculated for each image and plotted to produce a modulation transfer function (MTF) as illustrated in FIG. 13. Average pixel modulation may be calculated using techniques known to those skilled in the art, for example, according to the equation

$$M = \frac{peak - valley}{peak + valley} .$$

The average pixel modulation is plotted as a function of the inverse pixel dimension (1/mm). The resolution may be compared by looking at the pixel sizes that are resolved at certain specified modulations. At a 50% modulation, for example, the simulated pixelated scintillation detector without the window (i.e., on PSPMT) resolves at about 3.8/mm, whereas the simulated pixelated scintillation detector with the window (i.e., on glass plate) resolves at about 2.3/mm, which indicates a 1.65× improvement. A pixelated scintillation detector without the window may thus improve spatial resolution by enabling the use of smaller pixel sizes (e.g., up to 65% smaller).

Accordingly, the pixelated scintillation detector and method of making the detector, consistent with the embodiments described herein, allows the window to be eliminated from between the crystal and the photodetector. Eliminating the window (and the additional layer of optical coupling material) reduces the spread of scintillation light from the scintillation crystal and reduces (or eliminates) the refractive index mismatch that exists when the window is used with optical coupling material on each side. The elimination of the window may thus improve the optical isolation of the scintillation light being coupled into the position sensitive photodetector and the pixel to pixel alignment between the array of crystal pixel elements and detection positions of the position sensitive photodetector. As a result, a pixelated scintillation detector constructed as described herein may provide performance enhancements. In particular, performance may be enhanced by an improved energy resolution, an improved spatial resolution, an improved signal-to-noise (S/N) ratio, and an improved detection at low energies.

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention, which is not to be limited except by the following claims.

What is claimed is:

1. A scintillation detector comprising:
a position sensitive photodetector;
an array of crystal pixel elements; and
an optical coupling material between the position sensitive photodetector and the array of crystal pixel elements, the optical coupling material mechanically and optically coupling the array of crystal pixel elements directly to the position sensitive photodetector.

2. The scintillation detector of claim 1 further comprising a housing enclosing the array of crystal pixel elements and secured to the position sensitive photodetector.

3. The scintillation detector of claim 1 further comprising a reflective material around at least a portion of the crystal pixel elements.

4. The scintillation detector of claim 3 wherein the reflective material includes a powdered reflective material filling the spaces around and between the crystal pixel elements.

5. The scintillation detector of claim 4 further comprising a reflective material retaining structure positioned around the array of crystal pixel elements to retain the powdered reflective material.

6. The scintillation detector of claim 3 wherein the housing includes at least first and second housing portions, wherein the first housing portion is secured to the position sensitive photodetector and extends around sides of the array of crystal pixel elements to retain the powdered reflective material, and wherein the second housing portion is secured to the first housing portion and extends over an end of the array of crystal pixel elements.

7. The scintillation detector of claim 1 wherein the position sensitive photodetector is a position sensitive photomultiplier tube (PSPMT).

8. The scintillation detector of claim 1 wherein the housing is hermetically sealed to the position sensitive photodetector.

9. The scintillation detector of claim 1 wherein the optical coupling material has a thickness in a range of about ¼ mm to 2½ mm.

10. The scintillation detector of claim 1 wherein the optical coupling material is a clear optical epoxy.

11. The scintillation detector of claim 1 wherein the array of crystal pixel elements includes slots between the crystal pixel elements, and wherein the slots extend from one end of the array of crystal pixel elements to the optical coupling material.

12. A method of making a scintillation detector, comprising:
applying an optical coupling material between a scintillation crystal and a position sensitive photodetector to mechanically and optically couple the scintillation crystal and the position sensitive photodetector;
cutting the scintillation crystal while coupled to the position sensitive photodetector to form a pixelated scintillation crystal including an array of crystal pixel elements; and
applying a reflective material to the array of crystal pixel elements.

13. The method of claim 12 further comprising:
securing a housing to the position sensitive photodetector such that the housing encloses the pixelated scintillation crystal.

14. The method of claim 12 wherein applying the optical coupling material includes applying a clear optical epoxy and directly adhering the scintillation crystal to the position sensitive photodetector.

15. The method of claim 12 wherein cutting the scintillation crystal includes cutting the scintillation crystal using a wet cutting process.

16. The method of claim 12 further comprising securing the position sensitive photodetector during cutting such that at least a portion of the position sensitive photodetector is sealed off from coolant used in cutting the scintillation crystal.

17. The method of claim 12 further comprising positioning a reflective material retaining structure around the pixelated scintillation crystal, and wherein applying the reflective material includes filling spaces around and between the crystal pixel elements with a powdered reflective material.

18. The method of claim 13 wherein securing the housing comprises:
securing a first housing portion to the position sensitive photodetector before applying the reflective material, wherein the first housing portion is configured to retain the reflective material; and
securing a second housing portion to the first housing portion.

19. The method of claim 12 wherein the position sensitive photodetector is a position sensitive photomultiplier tube (PSPMT).

20. The method of claim 12 wherein the scintillation crystal is a hygroscopic crystal.

21. A method of detecting radiation, the method comprising:
providing a pixelated scintillation detector including a position sensitive photodetector and an array of crystal pixel elements mechanically and optically coupled directly to the position sensitive photodetector using an optical coupling material without a window;
applying radiation to the array of crystal pixel elements;
producing an output from the position sensitive photodetector in response to excitatory radiation; and
processing the output from the position sensitive photodetector to produce detected radiation information corresponding to each of the pixel elements in the array of crystal pixel elements, wherein the detected radiation information includes at least a flood image having an improved spatial resolution as compared to a flood image generated under the same conditions by a pixelated scintillation detector including an array of crystal pixel elements coupled to a position sensitive photodetector with a window.

22. The method of claim 21 wherein the array of crystal pixel elements has a pixel size, wherein an average pixel modulation calculated from the flood image for the pixelated scintillation detector without the window is the same as an average pixel modulation calculated from a flood image of a pixelated scintillation detector including an array of crystal pixel elements of a larger size coupled to a position sensitive photodetector using a window.

23. The method of claim 22 wherein the average pixel modulation is 50% and the pixelated scintillation detector without the window has a pixel size up to about 65% smaller than the pixelated scintillation detector with the window.

24. A pixelated scintillation detection system comprising:
a pixelated scintillation detector including a position sensitive photodetector and an array of crystal pixel elements mechanically and optically coupled directly to the position sensitive photodetector using an optical coupling material without a window; and
a signal processing system configured to process the output from the position sensitive photodetector to produce detected radiation information corresponding to each of the pixel elements in the array of crystal pixel elements, wherein the detected radiation information includes at least a flood image having an improved spatial resolution as compared to a flood image generated under the same conditions by a pixelated scintillation detector including an array of crystal pixel elements coupled to a position sensitive photodetector with a window.

25. The pixelated scintillation detection system of claim 25 wherein an average pixel modulation calculated from the flood image generated by the scintillation detector with the window is between about 10% and 60% higher than an average pixel modulation calculated from the flood image generated from the pixelated scintillation detector with the window.
